(19) United States
(12) Patent Application Publication
(10) Pub. No.: US 2026/0088786 A1
(43) Pub. Date: Mar. 26, 2026

(54) Multipath Amplifier Circuitry with Compact Transformers

(71) Applicant: Apple Inc., Cupertino, CA (US)

(72) Inventors: Fei Wang, Sunnyvale, CA (US); Xiang Guan, Saratoga, CA (US)

(21) Appl. No.: 18/895,232

(22) Filed: Sep. 24, 2024

(51) Int. Cl. H03F 3/68; H03F 1/56; H03F 3/24; H04B 1/04

(52) U.S. Cl. CPC H03F 3/68; H03F 1/56; H03F 3/245; H04B 1/0458; H03F 2200/294; H03F 2200/451; H04B 2001/0408

(57) ABSTRACT

Wireless circuitry may include multipath amplifier circuitry with a first amplifier on a first path and a second amplifier on a second path. The first and second paths may be coupled between an input and output networks. The input network, the output network, and/or an inter-stage matching network may include a transformer circuit. The transformer circuit may include a first transformer on the first path and a second transformer on the second path. The first transformer may overlap the second transformer on a substrate. The first transformer may be orthogonal to the second transformer such that current on the first transformer does not induce current on the second transformer and vice versa. This may serve to minimize the area consumed by the multipath amplifier circuitry while also preserving isolation between the first and second paths.

### FIELD

This disclosure relates generally to electronic devices, including electronic devices with wireless communications circuitry.

### BACKGROUND

Electronic devices are often provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals conveyed by an antenna are often fed through amplifier circuitry. It can be challenging to design satisfactory power amplifier circuitry for an electronic device. For example, if care is not taken, the amplifier circuitry might not exhibit sufficient levels of performance and can occupy an excessive amount of area in the electronic device

### SUMMARY

An electronic device may be provided with wireless circuitry. The wireless circuitry may include multipath amplifier circuitry. The multipath amplifier circuitry may include at least a first amplifier on a first path and a second amplifier on a second path. The first and second paths may be coupled in parallel between an input network and an output network. The input network, the output network, and/or an inter-stage matching network of the multipath amplifier circuitry may include a transformer circuit.

The transformer circuit may include a first transformer on the first path and a second transformer on the second path. The first transformer may overlap the second transformer on a substrate. The first transformer may be orthogonal to the second transformer such that current on the first transformer does not induce current on the second transformer and vice versa. The first transformer may include overlapping windings that laterally surround a central opening on the substrate. The second transformer may include overlapping windings having a crossover that configures the windings in the second transformer to laterally surround first and second openings. The first and second openings and the crossover may overlap the central opening. The windings of the first transformer may laterally surround the windings of the second transformer. This may serve to minimize the area consumed by the multipath amplifier circuitry while also preserving isolation between the first and second paths.

An aspect of the disclosure provides amplifier circuitry. The amplifier circuitry can include a first path. The amplifier circuitry can include a first amplifier on the first path. The amplifier circuitry can include a first transformer on the first path and operably coupled to the first amplifier. The amplifier circuitry can include a second path. The amplifier circuitry can include a second amplifier on the second path. The amplifier circuitry can include a second transformer on the second path and operably coupled to the second amplifier. The second transformer can overlap the first transformer. The second transformer can be orthogonal to the first transformer.

An aspect of the disclosure provides amplifier circuitry. The amplifier circuitry can include a first amplifier. The amplifier circuitry can include a second amplifier. The amplifier circuitry can include a substrate. The amplifier circuitry can include a first transformer operably coupled to an output of the first amplifier. The amplifier circuitry can include a second transformer operably coupled to an output of the second amplifier. The first transformer can include a first conductive trace on the substrate and laterally extending around a first opening on the substrate. The second transformer can include a second conductive trace on the substrate. The second conductive trace can include a crossover point that overlaps the first opening. The second conductive trace can laterally extend around second and third openings that overlap the first opening and that are smaller than the first opening.

An aspect of the disclosure provides wireless circuitry. The wireless circuitry can include an antenna. The wireless circuitry can include power amplifier circuitry communicatively coupled to the antenna and configured to transmit a radio-frequency signal using the antenna. The power amplifier circuitry can include a signal splitter. The power amplifier circuitry can include a signal combiner. The power amplifier circuitry can include a first path coupled between the signal splitter and the signal combiner and having a first amplifier, The power amplifier circuitry can include a second path coupled between the signal splitter and the signal combiner in parallel with the first path and having a second amplifier. The signal splitter can include a first transformer communicatively coupled to an input of the first amplifier. The signal splitter can include a second transformer communicatively coupled to an input of the second amplifier. The first transformer can laterally surround the second transformer, The first transformer can be orthogonal to the second transformer.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry that includes amplifier circuitry in accordance with some embodiments.

FIG. 3 is a block diagram of illustrative multipath amplifier circuitry in accordance with some embodiments.

FIG. 4 is a block diagram of illustrative multipath amplifier circuitry having multiple amplifier stages in accordance with some embodiments.

FIG. 5 is a circuit diagram of an illustrative transformer circuit that may be included in multipath amplifier circuitry in accordance with some embodiments.

FIG. 6 is a layout diagram showing different conductive layers of an illustrative transformer circuit that may be included in multipath amplifier circuitry in accordance with some embodiments.

FIG. 7 includes plots of operating characteristics for an illustrative transformer circuit of the type shown in FIGS. 5 and 6 in accordance with some embodiments.

FIG. 8 is a circuit diagram of an illustrative transformer circuit that may be included in an output network of multipath amplifier circuitry in accordance with some embodiments.

FIG. 9 is a layout diagram of an illustrative transformer circuit in an output network of multipath amplifier circuitry in accordance with some embodiments.

FIGS. 10-12 includes plots of operating characteristics for illustrative multipath amplifier circuitry of the type shown in FIGS. 8 and 9 in accordance with some embodiments.

FIG. 13 is a block diagram of illustrative multipath amplifier circuitry having parallel transmit paths in accordance with some embodiments.

FIG. 14 is a block diagram of illustrative multipath amplifier circuitry having parallel transmit and receive paths in accordance with some embodiments.

FIG. 15 is a circuit diagram of illustrative multipath amplifier circuitry having parallel transmit paths in accordance with some embodiments.

FIG. 16 is a circuit diagram of illustrative multipath amplifier circuitry having parallel transmit and receive paths in accordance with some embodiments.

### DETAILED DESCRIPTION

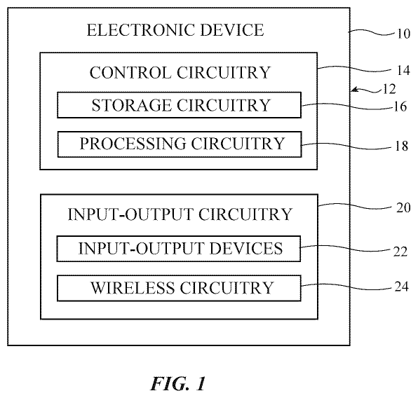

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

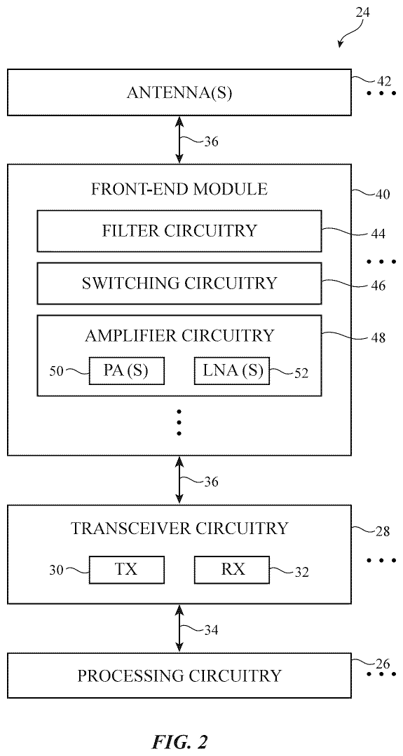

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be coupled to transceiver 28 over baseband path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single transceiver 28, a single front-end module 40, and a single antenna 42 for the sake of clarity. In general, wireless circuitry 24 may include any desired number of transceivers 28, any desired number of front-end modules 40, and any desired number of antennas 42. If desired, processing circuitry 26 may include different processing units (e.g., processors) coupled to one or more transceiver 28 over respective baseband paths 34. Each transceiver 28 may include a transmitter (TX) circuit 30 configured to output uplink signals to antenna 42, may include a receiver (RX) circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide baseband signals to transceiver 28 over baseband path 34. Transceiver 28 may further include circuitry for converting the baseband signals received from processing circuitry 26 into corresponding radio-frequency signals. For example, transceiver circuitry 28 may include mixer circuitry for up-converting (or modulating) the baseband signals to radio-frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over baseband path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40.

While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), a Wi-Fi® 7 band, wireless personal area network (WPAN) transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front-end module 40 may include one or more power amplifiers (PA) circuits 50 in the transmit (uplink) path. A power amplifier 50 (sometimes referred to as radio-frequency power amplifier circuitry, transmit amplifier circuitry, or amplifier circuitry) may be configured to amplify a radio-frequency signal without changing the signal shape, format, or modulation. Power amplifier 50 may, for example, be used to provide 10 dB of gain, 20 dB of gain, 10-20 dB of gain, less than 20 dB of gain, more than 20 dB of gain, or other suitable amounts of gain.

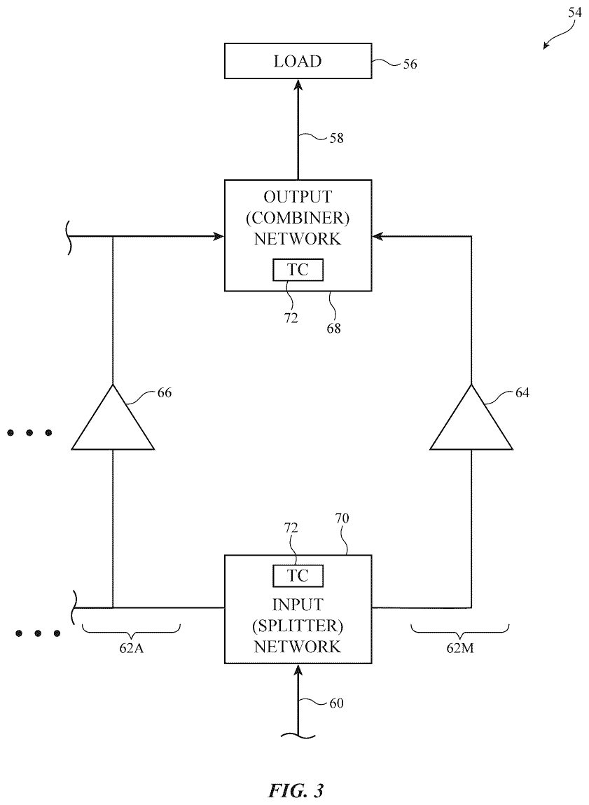

In implementations that are described herein as an example, one or more amplifiers in wireless circuitry 24 may include multipath amplifier circuitry. Multipath amplifier circuitry may include multiple amplifier paths coupled in parallel between an input path or load and an output path or load. FIG. 3 is a diagram of illustrative multipath amplifier circuitry 54 that may be used in wireless circuitry 24. Multipath amplifier circuitry 54 of FIG. 3 may, for example, form a PA 50 in front end module 40, a PA in transceiver 28, an LNA 52 in front end module 40, an LNA in transceiver 28, or any other desired radio-frequency amplifier elsewhere in wireless circuitry 24.

As shown in FIG. 3, multipath amplifier circuitry 54 may be coupled between an input signal path 60 and an output signal path 58. While referred to herein as input signal path 60 and output signal path 58, input signal path 60 and output signal path 58 may be formed from respective portions of the same signal path in wireless circuitry 24 (e.g., may form respective portions of a radio-frequency transmission line path 36 of FIG. 2). Output signal path 58 may be coupled to an output load such as load 56. Load 56 may be, for example, an antenna 42 (FIG. 2), other circuitry in a transmit chain coupled to an antenna 42, or any other desired load in wireless circuitry 24.

Multipath amplifier circuitry 54 may include input circuitry such as input network 70 (e.g., an input matching network and/or signal splitter). Input network 70 may have an input terminal (port) coupled to input signal path 60. Multipath amplifier circuitry 54 may include output circuitry such as output network 68 (e.g., an output matching network and/or signal combiner). Output network 68 may have an output terminal (port) coupled to signal path 58.

The input terminal of input network 70 may form the input of multipath amplifier circuitry 54.

The output terminal of output network 68 may form the output of multipath amplifier circuitry 54.

Multipath amplifier circuitry 54 may include a set of two or more amplifier paths 62 coupled in parallel between respective output terminals (ports) of input network 70 and respective input terminals (ports) of output network 68. Input network 70 may receive a radio-frequency signal over input signal path 60. Input network 70 may include signal splitting circuitry (e.g., a balanced signal splitter, quadrature hybrid splitting circuitry, matching circuitry, etc.) that splits the radio-frequency signal received from input signal path 60 between amplifier paths 62. Each amplifier path 62 may include one or more respective amplifiers that amplify the radio-frequency signal and that provide the amplified radio-frequency signal to output network 68. Output network 68 may include signal combining circuitry (e.g., a balanced signal combiner, one or more transformers, baluns, matching circuitry, etc.) that combines the amplified radio-frequency signals on each amplifier path 62 together on output signal path 58 (e.g., as a combined radio-frequency signal provided to load 56). Multipath amplifier circuitry 54 may drive load 56 using the combined radio-frequency signal on output signal path 58.

The amplifier paths 62 in multipath amplifier circuitry 54 may include a first amplifier path 62M (sometimes also referred to herein as main amplifier path 62M or primary amplifier path 62M). An amplifier such as amplifier 64 may be disposed on main amplifier path 62M. Amplifier 64 is sometimes also referred to herein as main amplifier 64 or primary amplifier 64. Main amplifier 64 may amplify a radio-frequency signal on main amplifier path 62M.

The amplifier paths 62 in multipath amplifier circuitry 54 may also include a second amplifier path 62A (sometimes also referred to herein as auxiliary amplifier path 62A or secondary amplifier path 62A) coupled in parallel with main amplifier path 62M between input network 70 and output network 68 (e.g., between the input and output of multipath amplifier circuitry 54). An amplifier such as amplifier 66 may be disposed on auxiliary amplifier path 62A. Amplifier 66 is sometimes also referred to herein as auxiliary amplifier 66 or secondary amplifier 66. Auxiliary amplifier 66 may amplify a radio-frequency signal on auxiliary amplifier path 62A. In the example of FIG. 3, multipath amplifier circuitry 54 is illustrated as including only a single auxiliary amplifier path 62A for the sake of clarity. If desired, multipath amplifier circuitry 54 may include multiple auxiliary amplifier paths 62A each including a different respective auxiliary amplifier 66.

In practice, the output power of each amplifier may increase linearly as a function of input power up until a certain power level, after which the amplifier becomes saturated and any further increase in input power does not produce a corresponding linear increase in output power. Main amplifier 64 may be configured or tuned to exhibit a linear response for a different range of input power levels and/or output power levels than auxiliary amplifier 66. Main amplifier 64 may, for example, be turned on and used to amplify a radio-frequency signal received over input signal path 60 up until a certain output power level, beyond which the main amplifier may no longer exhibit linear behavior. Once main amplifier 64 reaches this point, auxiliary amplifier 66 may be turned on and may help amplify the radio-frequency signal to reach higher power levels (e.g., power levels over which auxiliary amplifier 66 exhibits a linear response).

This may serve to maximize the range of output powers over which the multipath amplifier circuitry exhibits linear behavior while also ensuring that multipath amplifier circuitry 54 does not consume more power than needed, which increases the efficiency of the amplifier circuitry. Amplifiers 66 and 64 may, if desired, be different types of amplifiers that are optimized for amplifying signals at different power levels and/or with different characteristics. Amplifiers 66 and/or 64 may include, for example, a class A amplifier, a class AB amplifier, a class D amplifier, a class E amplifier, a class F amplifier, a class G amplifier, a class H amplifier, a class I amplifier, a class T amplifier, or other types of amplifiers.

Amplifiers 66 and 64 of two different types coupled together in this way using input network 70 and output network 68 are sometimes referred to collectively as a Doherty amplifier. Multipath amplifier circuitry 54 is sometimes also referred to herein as Doherty amplifier 54, Doherty amplifier circuitry 54, Doherty amplifier circuit 54, or multipath amplifier 54. Output network 68 is sometimes also referred to herein as Doherty output network 68 or Doherty output circuitry 68. Input network 70 is sometimes also referred to herein as Doherty input network 70 or Doherty input circuitry 70.

Multipath amplifier circuitry 54 may include one or more transformers integrated into one or more transformer circuits (TC) 72. For example, input network 70 may include a first transformer circuit 72 (e.g., an input transformer circuit) and output network 68 may include a second transformer circuit 72 (e.g., an output transformer circuit). The transformer circuit 72 in input network 70 may, for example, split a radio-frequency signal received over input signal path 60 onto main amplifier path 62M and auxiliary amplifier path 62A and/or may perform impedance matching (e.g., matching the input impedance of amplifier paths 62A and 62M to the impedance of input signal path 60). The transformer circuit 72 in output network 68 may, for example, combine a radio-frequency signal received over amplifier paths 62A and 62M onto output signal path 58 (e.g., as a combined signal on output signal path 58) and/or may perform impedance matching (e.g., matching the output impedance of amplifier paths 62A and 62M to the impedance of load 56). Multipath amplifier circuitry 54 may drive load 56 using the combined signal over output signal path 58.

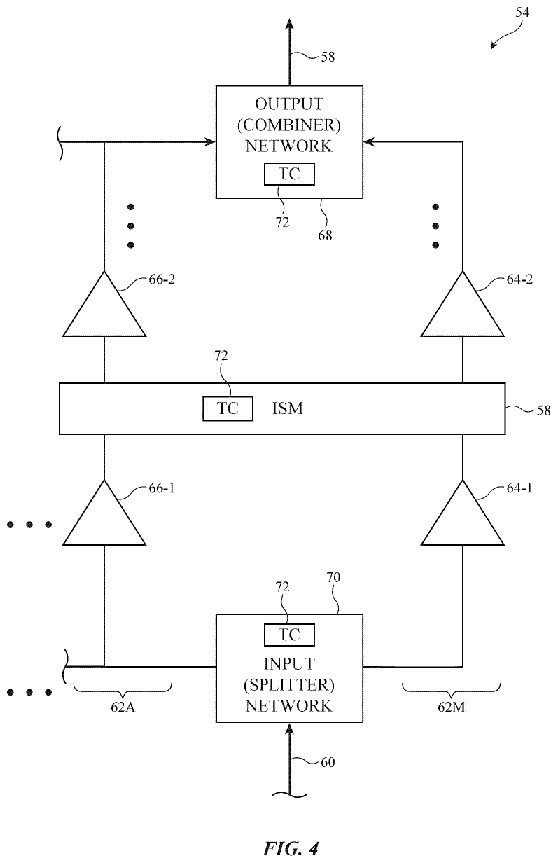

The example of FIG. 3 in which amplifier paths 62A and 62M each include a single amplifier represents a simplest case and is non-limiting. If desired, amplifier paths 62A and 62M may include multiple amplifier stages, as shown in the example of FIG. 4. As shown in FIG. 4, main amplifier path 62M may include at least two amplifiers 64-1 and 64-2 coupled in series between input network 70 and output network 68. Additionally or alternatively, auxiliary amplifier path 62A may include at least two amplifiers 66-1 and 66-2 coupled in series between input network 70 and output network 68. Amplifiers 64-1 and 66-1 may represent a first amplifier stage of multipath amplifier circuitry 54 whereas amplifiers 64-2 and 66-2 represent a second amplifier stage of multipath amplifier circuitry 54. If desired, multipath amplifier circuitry 54 may include impedance matching circuitry between each amplifier stage such as interstage matching network (ISM) 73 coupled in series between amplifiers 66-1 and 66-2 and coupled in series between amplifiers 64-1 and 64-2. If desired, ISM 73 may also include a transformer circuit 72. The transformer circuit 72 in ISM 73 may, for example, match the output impedance of amplifiers 66-1 and 64-1 to the input impedance of amplifiers 66-2 and 64-2. This may be generalized to any desired number of amplifier stages. Multipath amplifier circuitry 54 may include a respective ISM 73 between each of the stages if desired. Transformer circuit 72 is sometimes also referred to herein as transformer circuitry 72.

Each transformer circuit 72 in multipath amplifier circuitry 54 may include at least a first transformer and a second transformer. The first transformer may be coupled to main amplifier path 72M. The second transformer may be coupled to auxiliary amplifier path 72A. In some implementations, the first and second transformers are non-overlapping on an underlying substrate (e.g., a semiconductor substrate, a printed circuit board, etc.). However, implementing a transformer circuit 72 using non-overlapping transformers causes transformer circuit 72 to occupy an excessive amount of area on the underlying substrate (e.g., twice as much area as required for a single transformer on a single amplifier path).

In other implementations, the first transformer in a transformer circuit 72 may overlap the second transformer on the underlying substrate. This may reduce the area consumed by the transformer circuit in half relative to implementations where the first and second transformers in the transformer circuit are non-overlapping. However, if care is not taken, there will be a non-zero coupling coefficient between overlapping first and second transformers, which can reduce isolation between amplifier paths 62 and can cause multipath amplifier 54 to exhibit insufficient levels of performance. To mitigate these issues, transformer circuit 72 may include first and second transformers that are both overlapping and orthogonal to each other. The orthogonality of the first and second transformers effectively eliminates electromagnetic coupling between the first and second transformers, maximizing isolation between the amplifier paths.

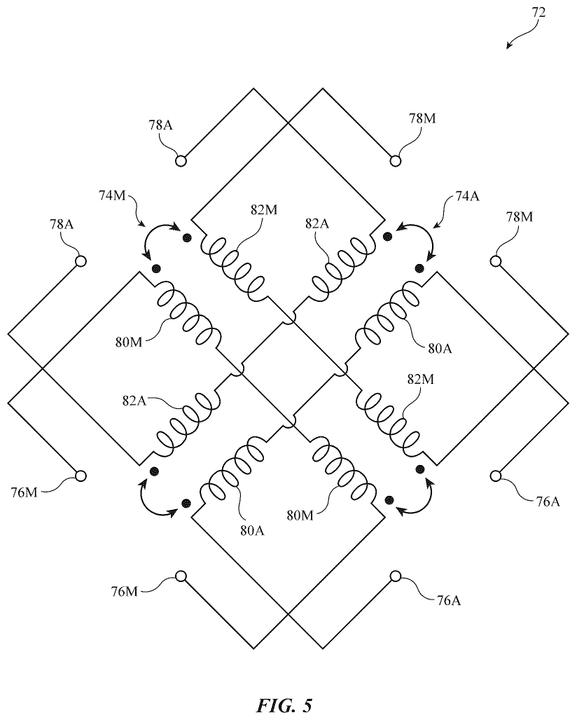

FIG. 5 is a circuit diagram of an illustrative transformer circuit 72 having orthogonal overlapping transformers. Transformer circuit 72 of FIG. 5 may, for example, be included in input network 70 (FIGS. 3 and 4), output network 68 (FIGS. 3 and 4), and/or ISM 73 (FIG. 4). As shown in FIG. 5, transformer circuit 72 may include a first transformer 74M disposed on main amplifier path 62M (FIGS. 3 and 4). Transformer 74M is sometimes also referred to herein as primary transformer 74M, main transformer 74M, or main amplifier path transformer 74M. Transformer circuit 72 may also include a second transformer 74A disposed on auxiliary amplifier path 62A (FIGS. 3 and 4). Transformer 74A is sometimes also referred to herein as secondary transformer 74A, auxiliary transformer 74A, or auxiliary amplifier path transformer 74A.

Transformer 74M may include a first winding, coil, or inductor such as primary winding 80M. Transformer 74M may also include second winding, coil, or inductor such as secondary winding 82M. Secondary winding 82M is electromagnetically coupled to primary winding 80M with a non-zero magnetic coupling coefficient k (sometimes also referred to herein as a coupling constant k). Primary winding 80M may be coupled to input port 76M of transformer 74M (e.g., primary winding 80M may extend between a first input terminal and a second input terminal of input port 76M). Secondary winding 82M may be coupled to output port 78M of transformer 74M (e.g., secondary winding 82M may extend between a first output terminal and a second output terminal of output port 78M).

Input port 76M may be communicatively coupled to the output of main amplifier 64 (e.g., when transformer circuit 72 is disposed in output network 68 of FIG. 3), to input signal path 60 (e.g., when transformer circuit 72 is disposed in input network 70 of FIGS. 3 and 4), to the output of amplifier 64-1 (e.g., when transformer circuit 72 is disposed in ISM 73 of FIG. 4), to the output of amplifier 64-2 (e.g., when transformer circuit is disposed in output network 68 of FIG. 4), or to any other signal source. Output port 78M may be communicatively coupled to output signal path 58 (e.g., when transformer circuit 72 is disposed in output network 68 of FIGS. 3 and 4), to the input of main amplifier 64 (e.g., when transformer circuit 72 is disposed in input network 70 of FIG. 3), to the input of amplifier 64-2 (e.g., when transformer circuit 72 is disposed in ISM 73 of FIG. 4), to the input of amplifier 64-1 (e.g., when transformer circuit 72 is disposed in input network 70 of FIG. 4), or to any other load.

In the example of FIG. 5, input port 76M includes a differential pair of input terminals that are coupled to a differential signal path of multipath amplifier circuitry 54 (e.g., in main amplifier path 62M and/or input signal path 60) and output port 78M includes a differential pair of output terminals that are coupled to a differential signal path of multipath amplifier circuitry 54 (e.g., in main amplifier path 62M and/or output signal path 58). This is illustrative and non-limiting. If desired, input port 76M may be implemented using a single ended input terminal that is coupled to a single-ended signal path (e.g., where one end of primary winding 80M is shorted to a reference potential such as ground) and/or output port 78M may be implemented using a single ended output terminal that is coupled to a single-ended signal path (e.g., where one end of secondary winding 82M is shorted to a reference potential such as ground).

Transformer 74A may include a first winding, coil, or inductor such as primary winding 80A. Transformer 74A may also include second winding, coil, or inductor such as secondary winding 82A. Secondary winding 82A is electromagnetically coupled to primary winding 80A with a non-zero coupling coefficient k (e.g., the same non-zero coupling coefficient as primary winding 80M or a different coupling coefficient than primary winding 80M).

Primary winding 80A may be coupled to input port 76A of transformer 74A (e.g., primary winding 80A may extend between a first input terminal and a second input terminal of input port 76A). Secondary winding 82A may be coupled to output port 78A of transformer 74A (e.g., secondary winding 82A may extend between a first output terminal and a second output terminal of output port 78A).

Input port 76A may be communicatively coupled to the output of auxiliary amplifier 66 (e.g., when transformer circuit 72 is disposed in output network 68 of FIG. 3), to input signal path 60 (e.g., when transformer circuit 72 is disposed in input network 70 of FIGS. 3 and 4), to the output of amplifier 66-1 (e.g., when transformer circuit 72 is disposed in ISM 73 of FIG. 4), to the output of amplifier 66-2 (e.g., when transformer circuit is disposed in output network 68 of FIG. 4), or to any other signal source. Output port 78A may be communicatively coupled to output signal path 58 (e.g., when transformer circuit 72 is disposed in output network 68 of FIGS. 3 and 4), to the input of auxiliary amplifier 66 (e.g., when transformer circuit 72 is disposed in input network 70 of FIG. 3), to the input of amplifier 66-2 (e.g., when transformer circuit 72 is disposed in ISM 73 of FIG. 4), to the input of amplifier 66-1 (e.g., when transformer circuit 72 is disposed in input network 70 of FIG. 4), or to any other load.

In the example of FIG. 5, input port 76A includes a differential pair of input terminals that are coupled to a differential signal path of multipath amplifier circuitry 54 (e.g., in auxiliary amplifier path 62A and/or input signal path 60) and output port 78A includes a differential pair of output terminals that are coupled to a differential signal path of multipath amplifier circuitry 54 (e.g., in auxiliary amplifier path 62A and/or output signal path 58). This is illustrative and non-limiting. If desired, input port 76A may be implemented using a single ended input terminal that is coupled to a single-ended signal path (e.g., where one end of primary winding 80A is shorted to a reference potential such as ground) and/or output port 78A may be implemented using a single ended output terminal that is coupled to a single-ended signal path (e.g., where one end of secondary winding 82A is shorted to a reference potential such as ground).

To minimize the area consumed by transformer circuit 72 and thus multipath amplifier circuitry 54, transformer 74M may overlap transformer 74A (e.g., the windings of transformer 74A may overlap the windings of transformer 74M and/or may overlap an opening surrounded by the windings of transformer 74M or vice versa). To eliminate electromagnetic coupling between transformers 74A and 74M, which may maximize isolation between the transformers and thus the different amplifier paths, transformer 74A may be orthogonal to transformer 74M. This means that the transformers are laid out and oriented such that the current flowing through transformer 74M produces a first magnetic field that does not induce current to flow through transformer 74A and such that current flowing through transformer 74A produces a second magnetic field that does not induce current to flow through transformer 74M, despite the fact that transformer 74M overlaps transformer 74A on an underlying substrate.

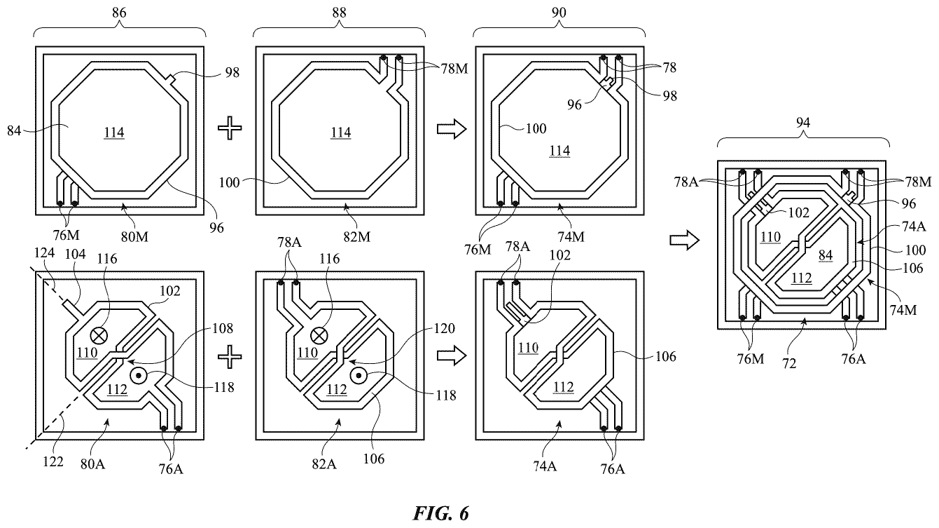

FIG. 6 is a layout diagram illustrating one example of how transformer circuit 72 may be disposed on an underlying substrate 84 with transformer 74A orthogonal to transformer 74M (and vice versa). Substrate 84 may be a semiconductor substrate, printed circuit board, or another substrate that includes a stack of interleaved metallization layers and insulator, dielectric, and/or semiconductor layers.

Portion 86 of FIG. 6 illustrates a first set of one or more metallization layers of substrate 84 that are used to form the primary windings 80M and 80A of transformers 74M and 74A respectively (e.g., one or more metallization layers on a first set of one or more dielectric, semiconductor, or insulator layers of substrate 84). Portion 88 of FIG. 6 illustrates a second set of one or more metallization layers of substrate 84 that are used to form the secondary windings 82M and 82A of transformers 74M and 74A respectively (e.g., one or more metallization layers on a second set of one or more dielectric, semiconductor, or insulator layers of substrate 84).

Portion 90 of FIG. 6 illustrates the layout of transformer 74M (including both primary winding 80M and secondary winding 82M) and illustrates transformer 74A (including both primary winding 80A and secondary winding 82A) on substrate 84. Portion 94 of FIG. 6 illustrates the layout of transformer circuit 72 on substrate 84 (e.g., including both transformer 74M and 74A).

As shown in the top half of portion 86 of FIG. 6, the primary winding 80M of transformer 74M may include a conductive trace 96 that extends between terminals of input port 76M and that extends laterally around a central opening 114. Conductive trace 96 is illustrated in the example of FIG. 6 as including one full loop, turn, coil, or winding around central opening 114. This is illustrative and, in general, conductive trace 96 may include any desired number of loops, turns, coils, or windings around central opening 114. If desired, conductive trace 96 may include a center tap conductor, contact, or terminal such as center tap 98. Center tap 98 may, for example, be disposed halfway between the terminals of input port 76M. Center tap 98 may be replaced with a tap at other locations along the length of conductive trace 96 or may be omitted if desired.

As shown in the top half of portion 88 of FIG. 6, the secondary winding 82M of transformer 74M may include a conductive trace 100 that extends between terminals of output port 78M and that extends laterally around a central opening 114. Output port 78M may be located at an opposite side or corner of transformer 74M from input port 76M or may be at another location (e.g., a same side or corner as input port 76M). Conductive trace 100 is illustrated in the example of FIG. 6 as including one full loop, turn, coil, or winding around central opening 114. This is illustrative and, in general, conductive trace 100 may include any desired number of loops, turns, coils, or windings around central opening 114. As shown in the top half of portion 90 of FIG. 6, the conductive trace 100 of secondary winding 82M may overlap the conductive trace 96 of primary winding 80M in transformer 74M. Center tap 98 of primary winding 80M may, if desired, extend between the terminals of output port 78M.

Returning to the bottom half of portion 86 of FIG. 6, the primary winding 80A of transformer 74A may include a conductive trace 102 that extends between terminals of input port 76A. Conductive trace 102 may be arranged in a figure eight pattern and may cross over itself at crossover point 108 (e.g., using conductive vias extending between multiple metallization layers of substrate 84) such that conductive trace 102 laterally extends around both a first opening 110 and a second opening 112. Parallel segments of conductive trace 102 extending from crossover point 108 may extend parallel to linear axis 122 and may separate opening 110 from opening 112. Openings 110 and 112 may each span an area less than or equal to half the area spanned by central opening 114 of transformer 74M. If desired, conductive trace 102 may include a center tap conductor, contact, or terminal such as center tap 104. Center tap 104 may, for example, be disposed halfway between the terminals of input port 76A (e.g., extending along a linear axis 124 orthogonal to axis 122). Center tap 104 may be replaced with a tap at other locations along the length of conductive trace 102 or may be omitted if desired. Alternatively, the parallel segments of conductive trace 102 extending away from crossover point 108 may extend parallel to linear axis 124 if desired (e.g., transformer 74A may be oriented orthogonal to the orientation shown in FIG. 6).

As shown in the bottom half of portion 88 of FIG. 6, the secondary winding 82A of transformer 74A may include a conductive trace 106 that extends between terminals of input port 76A. Output port 78A may be located at an opposite side or corner of transformer 74A from input port 76A or may be at another location (e.g., a same side or corner as input port 76A). Conductive trace 106 may be arranged in a figure eight pattern and may cross over itself at crossover point 120 such that conductive trace 106 laterally extends around both opening 110 and opening 112. Parallel segments of conductive trace 106 extending from crossover point 120 may extend parallel to linear axis 122 and may separate opening 110 from opening 112. Alternatively, the parallel segments of conductive trace 106 extending away from crossover point 120 may extend parallel to linear axis 124 if desired (e.g., transformer 74A may be oriented orthogonal to the orientation shown in FIG. 6).

As shown in the bottom half of portion 90 of FIG. 6, the conductive trace 106 of secondary winding 82A may overlap the conductive trace 102 of primary winding 80A in transformer 74A. Crossover point 120 of secondary winding 82A may overlap crossover point 108 of primary winding 80A. Center tap 104 of primary winding 80A may, if desired, extend between the terminals of output port 78A. As shown in portion 94 of FIG. 6, transformer 74A and its conductive traces 102 and 106 may overlap the central opening 114 of transformer 74M in transformer circuit 72. Openings 110 and 112 in transformer 74A may overlap respective portions of the central opening 114 of transformer 74M. Conductive trace 100 and conductive trace 96 of transformer 74M may laterally extend around conductive traces 102 and 106 of transformer 74A. Input port 76M, input port 76A, output port 78A, and output port 78M may extend from conductive traces 96, 102, 106, and 100, respectively, at different corners of transformer circuit 72 (e.g., to facilitate coupling of the signal path to each of the ports).

During signal transmission, current may flow along conductive trace 102 between the input terminals of input port 76A. This current may induce a corresponding current to flow along conductive trace 106 between the output terminals of output port 78A (e.g., due to the non-zero coupling coefficient between conductive trace 102 and the overlapping conductive trace 106). The current flowing along conductive trace 102 and the current flowing along conductive trace 106 may produce a magnetic field that is oriented in a first direction within opening 110 (e.g., in the direction of arrow 116) and may produce a magnetic field that is oriented in a second direction within opening 112 that is opposite the first direction (e.g., in the direction of arrow 118). This magnetic field may electromagnetically couple primary winding 80A to secondary winding 82A within transformer 74A.

However, because the magnetic field in opening 110 is opposite in direction to the magnetic field in opening 112 (and of equal magnitude), the magnetic field in opening 110 may cancel out the magnetic field in opening 112 from the perspective of the surrounding transformer 74M. This causes both primary winding 80A and secondary winding 82A to exhibit a coupling coefficient of zero with primary winding 80M and secondary winding 82M of transformer 74M. Because of this, current flowing through conductive traces 102 and 106 does not induce current to flow through conductive traces 96 and 100. Conversely, current flowing through conductive traces 96 and 100 does not induce current to flow through conductive traces 102 and 106. In this way, windings 80A and 82A and thus transformer 74A may be orthogonal to windings 80M and 82M and thus transformer 74M. This orthogonality maximizes isolation between transformers 74A and 74M and between the corresponding amplifier paths coupled to each transformer while also allowing transformer circuit 72 to span half the area on substrate 84 as transformer 74M and 74A separately.

The example of FIG. 6 is illustrative and non-limiting. In general, the conductive traces of transformers 74A and 74M may follow any desired paths having any desired number of straight and/or curved segments and may have any desired shape having any desired number of straight and/or curved edges. Windings 80M, 82M, 80A, and 82A may include any desired number of turns and may be provided with other relative orientations that maintain orthogonality between the transformers. If desired, transformer circuit 72 may include a third transformer (not shown) overlapping transformers 74A and 74M and that is orthogonal to both transformers 74A and 74M. The third transformer may, for example, be arranged in a figure eight pattern similar to transformer 74A but where the parallel segments extending away from its crossover point extend parallel to linear axis 124 rather than linear axis 122 (e.g., the third transformer may be rotated by 90 degrees with respect to transformer 74A). The conductive traces used to form each transformer may be disposed in one, more than one, or any desired number of metallization layers of substrate 84.

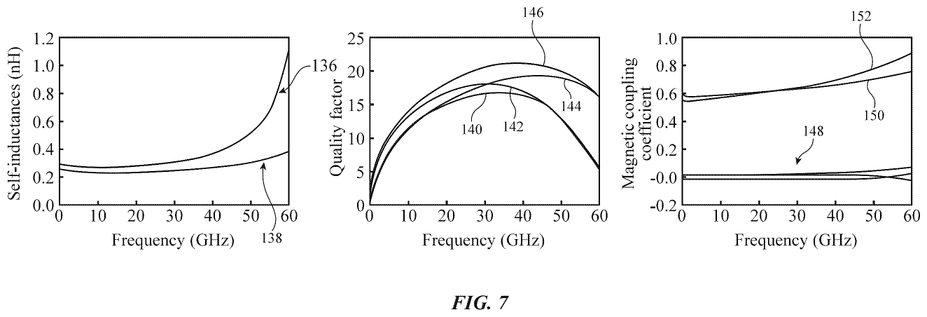

FIG. 7 includes plots of various performance characteristics of transformer circuit 72. Curves 138 plot the self-inductances of primary winding 80M and secondary winding 82M as a function of frequency. Curves 136 plot the self-inductances of primary winding 80A and secondary winding 82A as a function of frequency.

Curve 140 plots the quality (Q) factor of secondary winding 82A. Curve 142 plots the Q factor of primary winding 80A. Curve 144 plots the Q factor of secondary winding 82M. Curve 146 plots the Q factor of primary winding 80M. As shown by curves 140-146, each winding may exhibit a relatively high Q factor (e.g., greater than 10-15 across a frequency band of operation of the multipath amplifier circuitry).

Curve 152 plots the coupling coefficient between primary winding 80A and secondary winding 82A. Curve 150 plots the coupling coefficient between primary winding 80M and secondary winding 82M. Curves 148 plot the coupling coefficients between the windings of transformer 74M and the windings of transformer 74A. As shown by curves 148, the orthogonality of transformers 74A and 74M causes the coupling coefficients between the transformers to be zero or close to zero (e.g., less than or equal to 0.1 across the frequency band of operation of the amplifier circuitry, which may include any desired frequencies between 0 GHz and 60 GHz as one example). This maximizes isolation between the amplifier paths and thus the performance of multipath amplifier circuitry 54. As shown by curves 152 and 150, despite the orthogonality between transformers 74M and 74A, there may be sufficient coupling between the windings within transformer 74M to pass current from input port 76M onto output port 78M and there may be sufficient coupling between the windings within transformer 74A to pass current from input port 76A onto output port 78A. The example of FIG. 7 is illustrative and non-limiting. Curves 136-152 may have other shapes in practice. The amplifier circuitry may amplify signals in any desired frequency band at any desired frequencies.

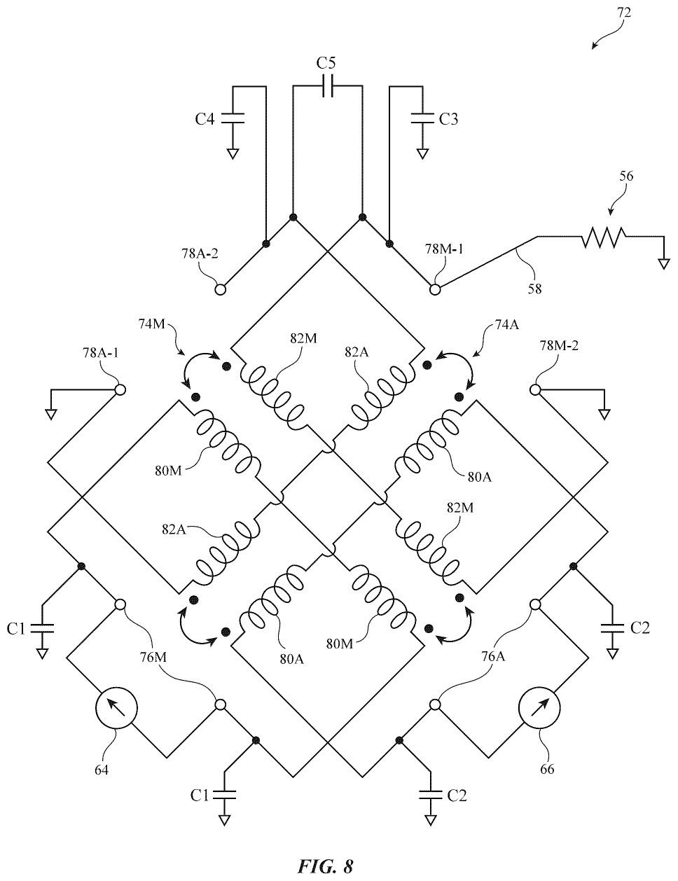

FIG. 8 is a circuit diagram showing one example of how transformer circuit 72 may be implemented in output network 68 of FIGS. 3 and 4. As shown in FIG. 8, the output of main amplifier 64 (modeled as a current source in FIG. 8) may be coupled to input port 76M of transformer 74M. If desired, shunt capacitances C1 may couple the input terminals of input port 76M to a reference potential such as ground (e.g., for impedance matching, filtering, etc.). Similarly, the output of auxiliary amplifier 66 (modeled as a current source in FIG. 8) may be coupled to input port 76A of transformer 74A. If desired, shunt capacitances C2 may couple the input terminals of input port 76A to a reference potential such as ground (e.g., for impedance matching, filtering, etc.).

Output port 78M of transformer 74M may include a first output terminal 78M-1 and a second output terminal 78M-2. Output terminal 78M-2 may be shorted to a reference potential such as ground. Output terminal 78M-1 may form the output terminal of transformer circuit 72 (e.g., a signal combiner circuit) and may be coupled to load 56 over output signal path 58. Output port 78A of transformer 74A may include a first output terminal 78A-1 and a second output terminal 78A-2. Output terminal 78A-1 may be shorted to a reference potential such as ground. Output terminal 78A-2 may be coupled to output terminal 78M-1 of transformer 74M and thus the output of transformer circuit 72 by capacitor C5. If desired, a shunt capacitor C4 may couple output terminal 78A-2 to a reference potential such as ground. If desired, a shunt capacitor C3 may couple output terminal 78M-1 to a reference potential such as ground.

During signal transmission, main amplifier 64 may produce current that flows through primary winding 80M of transformer 74M. This current may induce current on secondary winding 82M of transformer 74M (e.g., via the non-zero coupling coefficient shown by curve 150 of FIG. 7). At the same time, auxiliary amplifier 66 may produce current that flows through primary winding 80A of transformer 74A. This current may induce current on secondary winding 82A of transformer 74A (e.g., via the non-zero coupling coefficient shown by curve 152 of FIG. 7). The current in secondary winding 82A may be combined with the current in secondary winding 82M via capacitor C5, causing transformer circuit 72 to output the combined current through output terminal 78M-1. Shunt capacitor C4 and C3 and capacitor C5 may perform impedance matching and/or filtering for the combination of signals from transformers 74A and 74M onto output signal path 58.

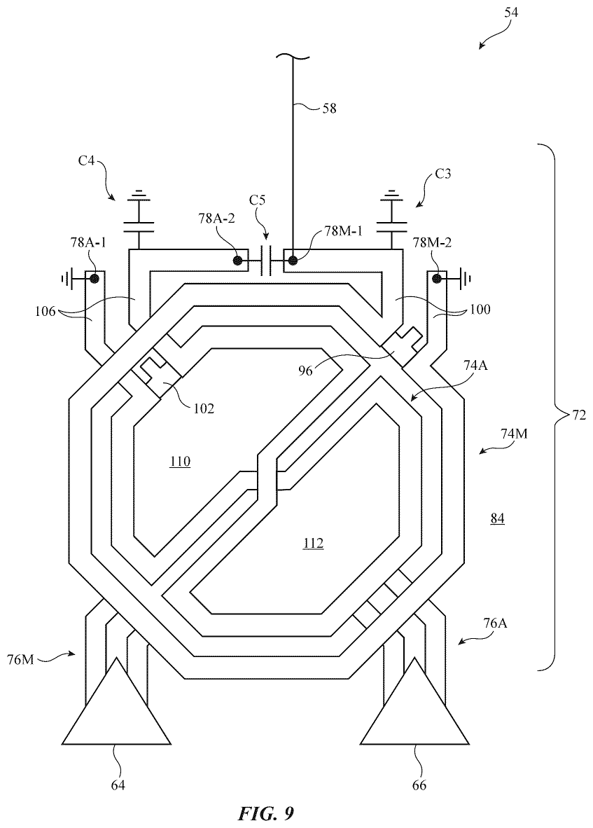

FIG. 9 is a layout diagram of the transformer circuit 72 of FIG. 8. As shown in FIG. 9, the output of main amplifier 64 may be coupled to conductive trace 96 of transformer 74M at input port 76M. The output of auxiliary amplifier 66 may be coupled to conductive trace 102 of transformer 74A at input port 76A. Output terminal 78A-1 on conductive trace 106 of transformer 74A may be coupled to ground. Output terminal 78M-2 on conductive trace 100 of transformer 74M may be coupled to ground. Output terminal 78A-2 on conductive trace 106 of transformer 74A may be coupled to ground by capacitor C4 and may be coupled to output terminal 78M-1 on conductive trace 100 of transformer 74M by capacitor C5. Output terminal 78M-1 may be coupled to output signal path 58.

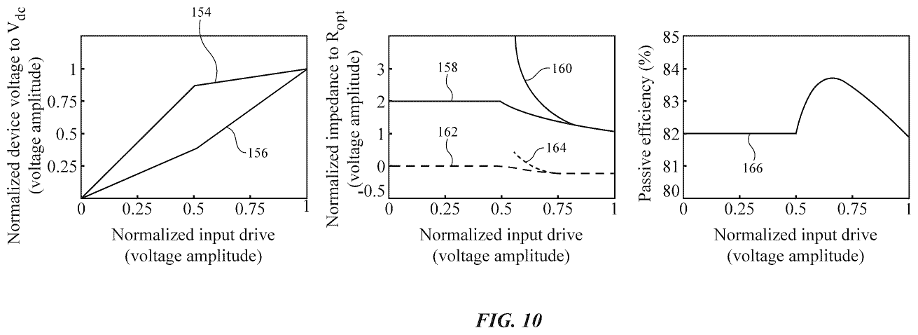

FIGS. 10-12 include plots of various performance characteristics of multipath amplifier circuitry 54 when provided with transformer circuit 72 of FIGS. 8 and 9 in output network 68 (FIGS. 3 and 4). Curve 156 of FIG. 10 plots the output voltage of auxiliary amplifier 66 as a function of normalized input drive voltage amplitude. Curve 154 plots the output voltage of main amplifier 64. Curve 158 plots the real component of the load impedance of main amplifier 64 as a function of normalized input drive voltage amplitude. Curve 160 plots the real component of the load impedance of auxiliary amplifier 66. Curve 162 plots the imaginary component of the load impedance of main amplifier 64. Curve 164 plots the imaginary component of the load impedance of auxiliary amplifier 66. Curve 166 plots the passive efficiency of the circuitry as a function of normalized input drive voltage amplitude. As shown by curve 166, the output network may exhibit a relatively high passive efficiency, and thus the multipath amplifier circuitry may exhibit a relatively high efficiency over load modulations, power backoffs, and/or voltage amplitudes.

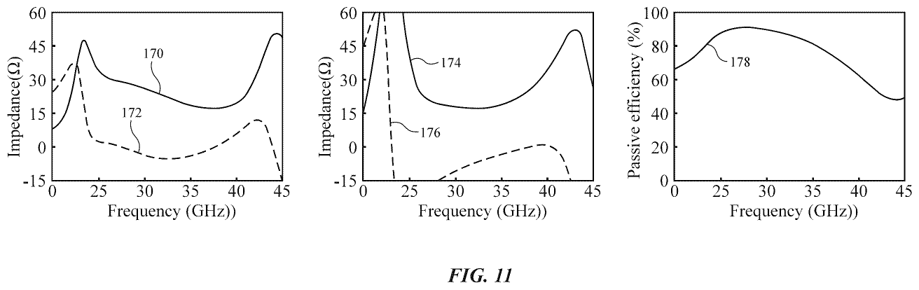

Curve 170 of FIG. 11 plots the real component of the load impedance of main amplifier 64 as a function of frequency at the maximum output power level of main amplifier 64. Curve 172 plots the imaginary component of the load impedance of main amplifier 64 as a function of frequency at the maximum output power level of main amplifier 64. Curve 174 plots the real component of the load impedance of auxiliary amplifier 66 as a function of frequency at the maximum output power level of auxiliary amplifier 66. Curve 176 plots the imaginary component of the load impedance of auxiliary amplifier 66 as a function of frequency at the maximum output power level of auxiliary amplifier 66. Curve 178 plots the passive efficiency of the circuitry as a function of frequency. As shown by curve 178, the output network may exhibit a relatively high passive efficiency, and thus multipath amplifier circuitry 54 may exhibit a relatively high efficiency over its operating bandwidth.

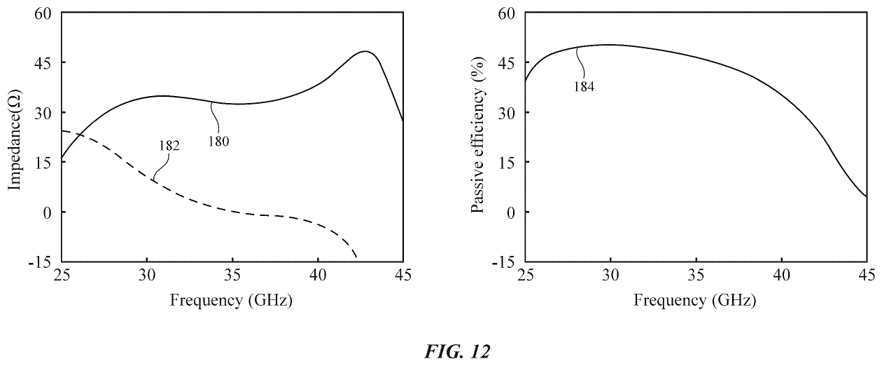

Curve 180 of FIG. 12 plots the real component of the load impedance of main amplifier 64 as a function of frequency at a 6 dB power backoff level of main amplifier 64. Curve 182 plots the imaginary component of the load impedance of main amplifier 64 as a function of frequency at the 6 dB power backoff level of main amplifier 64. Curve 184 plots the passive efficiency of the circuitry as a function of frequency. As shown by curve 184, the output network may exhibit a relatively high passive efficiency, and thus multipath amplifier circuitry 54 may exhibit relatively high efficiency over its operating bandwidth. The example of FIGS. 10-12 is illustrative and non-limiting. Curves 154-182 may have other shapes in practice. The amplifier circuitry may amplify signals in any desired frequency band at any desired frequencies.

The example of FIGS. 3 and 4 in which multipath amplifier circuitry 54 includes multiple amplifier paths that are coupled between a signal splitter (e.g., input network 70) and a signal combiner (e.g., output network 68) is illustrative and non-limiting. Put differently, multipath amplifier circuitry 54 need not be a Doherty amplifier having a main amplifier path and one or more auxiliary amplifier paths. More generally, multipath amplifier circuitry 54 may include multiple amplifier paths coupled in parallel between any desired input and output circuitry.

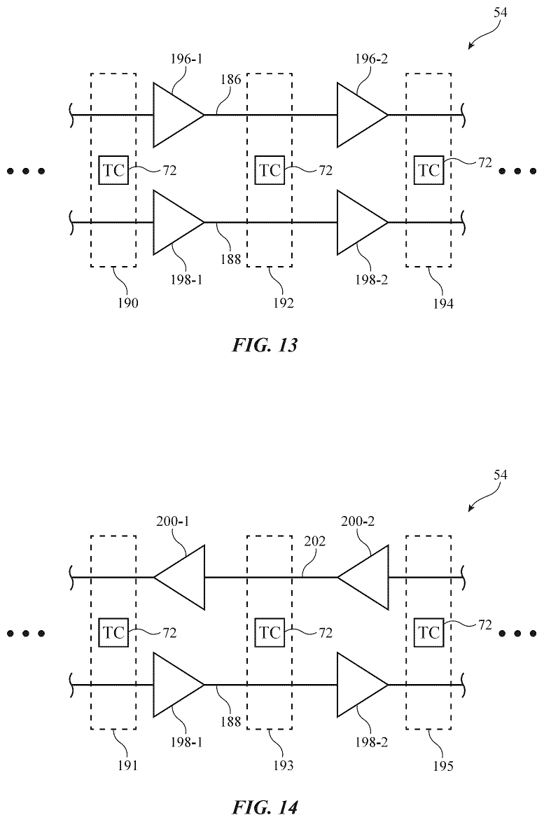

FIG. 13 illustrates another example in which multipath amplifier circuitry 54 includes multiple parallel transmit paths that are not split from a single input path or combined onto a single output path, such as a first transmit path 186 and a second transmit path 188. As shown in FIG. 13, transmit path 186 may include set of one or more amplifiers 196 (e.g., power amplifiers) such as amplifiers 196-1 and 196-2. Transmit path 186 may include a set of one or more amplifiers 198 (e.g., power amplifiers) such as amplifiers 198-1 and 198-2.

Multipath amplifier circuitry 54 may include an input matching network 190 on transmit paths 186 and 188 and coupled to the inputs of amplifiers 196-1 and 198-1, may include an ISM 192 on transmit paths 186 and 188 and coupled between the outputs of amplifiers 196-1 and 198-1 and the inputs of amplifiers 196-2 and 198-2, and/or may include an output matching network 194 on transmit paths 186 and 188 and coupled to the outputs of amplifiers 196-2 and 198-2. This may be generalized to any desired number of amplifier stages. Input matching network 190, ISM 192, and/or output matching network 194 may each include a corresponding transformer circuit 72 having orthogonal transformers 74A and 74M as shown and described in connection with FIGS. 5-12 (e.g., where transmit path 186 forms the main amplifier path of FIGS. 5-12 and where transmit path 188 forms the auxiliary amplifier path of FIGS. 5-12).

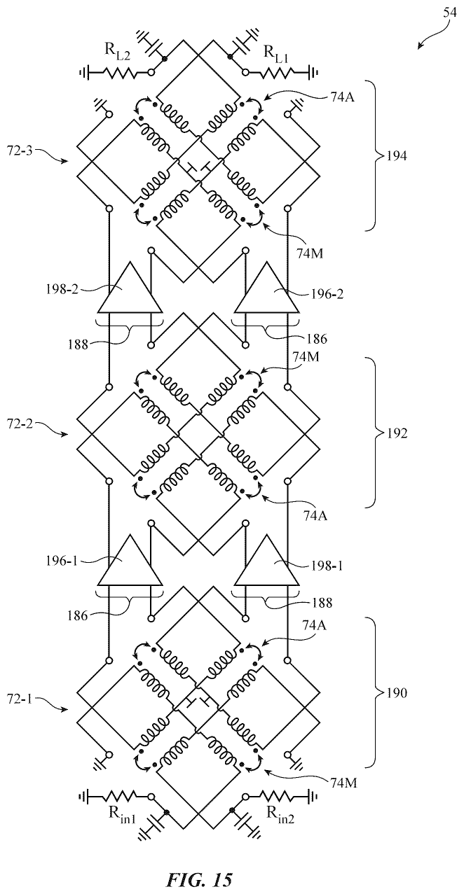

FIG. 14 illustrates another example in which multipath amplifier circuitry includes parallel transmit and receive paths. As shown in FIG. 14, transmit path 186 of FIG. 13 may be replaced with a receive path such as receive path 202. Receive path 202 may include set of one or more amplifiers 200 (e.g., low noise amplifiers) such as amplifiers 200-1 and 200-2. A first matching network 191 may be disposed on transmit path 188 and receive path 202. An ISM 193 may be disposed on transmit path 188 and receive path 202. A second matching network 195 may be disposed on transmit path 188 and receive path 202. This may be generalized to any desired number of amplifier stages. Matching network 191, ISM 193, and/or matching network 195 may each include a corresponding transformer circuit 72 having orthogonal transformers 74A and 74M as shown and described in connection with FIGS. 5-12 (e.g., where transmit path 188 forms the main amplifier path of FIGS. 5-12 and where receive path 202 forms the auxiliary amplifier path of FIGS. 5-12). Transmit paths 188 and 186 are sometimes also referred to herein as transmit chains. Receive path 202 is sometimes also referred to herein as receive chain 202.

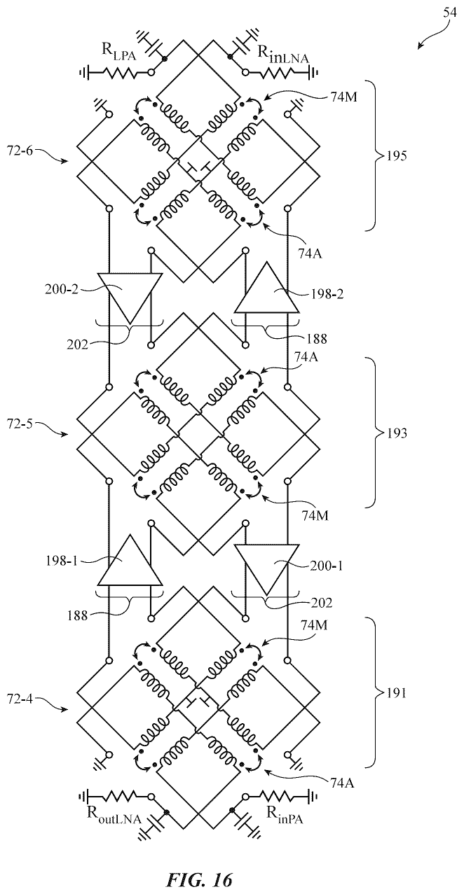

FIG. 15 is a circuit diagram showing one example in which multipath amplifier circuitry 54 of FIG. 13 is provided with transformer circuits 72 in input matching network 190, ISM 192, and output matching network 194. As shown in FIG. 15, input matching network 190 may include a first transformer circuit 72-1. Transformer circuit 72-1 may include a first transformer 74M in transmit path 188 and coupled between the input of amplifier 198-1 on transmit path 188 and input load Rᵢₙ₁. Transformer circuit 72-1 may also include a first transformer 74A in transmit path 186 and coupled between the input of amplifier 196-1 on transmit path 186 and input load Rᵢₙ₂. The first transformer 74M in transformer circuit 72-1 may be overlapping with and orthogonal to the first transformer 74A in transformer circuit 72-1.

Transmit paths 188 and 186 are illustrated as differential signal paths in the example of FIG. 15 but may, if desired, be implemented as single-ended signal paths.

ISM 192 may include a second transformer circuit 72-2. Transformer circuit 72-2 may include a second transformer 74M on transmit path 188 and coupled between the output of amplifier 198-1 and the input of amplifier 198-2 on transmit path 188. Transformer circuit 72-2 may also include a second transformer 74A on transmit path 186 and coupled between the output of amplifier 196-1 and the input of amplifier 196-2 on transmit path 186. The second transformer 74M in transformer circuit 72-2 may be overlapping with and orthogonal to the second transformer 74A in transformer circuit 72-2.

Output matching network 194 may include a third transformer circuit 72-3. Transformer circuit 72-3 may include a third transformer 74M in transmit path 188 and coupled between the output of amplifier 198-2 and output load R_{L1}. Transformer circuit 72-3 may also include a third transformer 74A in transmit path 186 and coupled between the output of amplifier 196-2 and output load R_{L2}. The third transformer 74M in output matching network 194 be overlapping with and orthogonal to the third transformer 74A in transformer circuit 72-3. Transformer circuits 72-1, 72-2, and 72-3 may configure multipath amplifier circuitry 54 to consume a minimal amount of area in device 10 while also maximizing isolation between transmit paths 186 and 188.

FIG. 16 is a circuit diagram showing one example in which multipath amplifier circuitry 54 of FIG. 14 is provided with transformer circuits 72 in matching network 191, ISM 193, and output matching network 195. As shown in FIG. 16, matching network 191 may include a first transformer circuit 72-4. Transformer circuit 72-4 may include a first transformer 74M in transmit path 188 and coupled between the input of amplifier 198-1 on transmit path 188 and input load R_{inPA}. Transformer circuit 72-4 may also include a first transformer 74A in receive path 202 and coupled between the output of amplifier 200-1 on receive path 202 and an output load R_{outLNA}. The first transformer 74M in transformer circuit 72-4 may be overlapping with and orthogonal to the first transformer 74A in transformer circuit 72-4. Transmit path 188 and receive path 202 are illustrated as differential signal paths in the example of FIG. 16 but may, if desired, be implemented as single-ended signal paths. Matching network 191 may form an input matching network for transmit path 188 and may form an output matching network for receive path 202.

ISM 193 may include a second transformer circuit 72-5. Transformer circuit 72-5 may include a second transformer 74M on transmit path 188 and coupled between the output of amplifier 198-1 and the input of amplifier 198-2 on transmit path 188. Transformer circuit 72-5 may also include a second transformer 74A on receive path 202 and coupled between the output of amplifier 200-2 on receive path 202 and the input of amplifier 200-1. The second transformer 74M in transformer circuit 72-5 may be overlapping with and orthogonal to the second transformer 74A in transformer circuit 72-5.

Matching network 195 may include a third transformer circuit 72-6. Transformer circuit 72-6 may include a third transformer 74M in transmit path 188 and coupled between the output of amplifier 198-2 and output load R_{LPA}. Transformer circuit 72-6 may also include a third transformer 74A in receive path 202 and coupled between the input of amplifier 200-2 and input load R_{inLNA}. The third transformer 74M in transformer circuit 72-6 may be overlapping with and orthogonal to the third transformer 74A in transformer circuit 72-6. Matching network 195 may form an input matching network for receive path 202 and may form an output matching network for transmit path 188. Transformer circuits 72-4, 72-5, and 72-6 may configure multipath amplifier circuitry 54 to consume a minimal amount of area in device 10 while also maximizing isolation between transmit path 186 and receive path 202.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

The methods and operations described above in connection with FIGS. 1-16 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

For one or more aspects, at least one of the components set forth in one or more of the preceding figures may be configured to perform one or more operations, techniques, processes, or methods as set forth in the example section below.

### Examples

In the following sections, further exemplary aspects are provided.

Example 1 includes amplifier circuitry comprising: a first path; a first amplifier on the first path; a first transformer on the first path and operably coupled to the first amplifier; a second path; a second amplifier on the second path; and a second transformer on the second path and operably coupled to the second amplifier, wherein the second transformer overlaps the first transformer, and the second transformer is orthogonal to the first transformer.

Example 2 includes the amplifier circuitry of example 1, wherein the first transformer comprises a first winding and a second winding characterized by a first coupling coefficient and the second transformer comprises a third winding and a fourth winding characterized by a second coupling coefficient.

Example 3 includes the amplifier circuitry of example 2, wherein the first winding exhibits first additional coupling coefficients with the third and fourth windings that are less than the first and second coupling coefficients, and the second winding exhibits second additional coupling coefficients with the third and fourth windings that are less than the first and second coupling coefficients.

Example 4 includes the amplifier circuitry of example 2, further comprising: a substrate, wherein the first winding includes a first conductive trace on the substrate and extending around a central opening, and the second winding includes a second conductive trace on the substrate, overlapping the first conductive trace, and extending around the central opening.

Example 5 includes the amplifier circuitry of example 4, wherein: the third winding includes a third conductive trace on the substrate, the third conductive trace includes a crossover overlapping the central opening, and the third conductive trace extends around a first opening and a second opening that overlap the central opening.

Example 6 includes the amplifier circuitry of example 5, wherein: the fourth winding includes a fourth conductive trace on the substrate and overlapping the third conductive trace, the fourth conductive trace includes an additional crossover overlapping the crossover of the third conductive trace, and the fourth conductive trace extends around the first opening and the second opening.

Example 7 includes the amplifier circuitry of example 6, wherein the first conductive trace laterally surrounds the third conductive trace on a first layer of the substrate.

Example 8 includes the amplifier circuitry of example 7, wherein the second conductive trace laterally surrounds the fourth conductive trace on a second layer of the substrate.

Example 9 include the amplifier circuitry of example 6, further comprising: a signal splitter that couples an input signal path to the first and second paths, wherein the signal splitter includes the first and second transformers.

Example 10 include the amplifier circuitry of example 6, further comprising: a signal combiner that couples the first and second paths to an output signal path, wherein the signal combiner includes the first and second transformers.

Example 11 includes the amplifier circuitry of example 10, wherein: the first winding is coupled to an output of the first amplifier, the third winding is coupled to an output of the second amplifier, the second winding extends from a first terminal to a second terminal, the fourth winding extends from a third terminal to a fourth terminal, the first terminal is coupled to a reference potential, the third terminal is coupled to the reference potential, the second terminal is coupled to the fourth terminal by a capacitor, and the second terminal is coupled to the output signal path.

Example 12 includes the amplifier circuitry of example 6, further comprising: a third amplifier on the first path; a fourth amplifier on the second path; and an inter-stage matching network on the first and second paths, wherein the inter-stage matching network includes the first and second transformers, the first transformer is coupled between the first and third amplifiers, and the second transformer is coupled between the second and fourth amplifiers.

Example 13 includes the amplifier circuitry of example 1, wherein the first path comprises a transmit path, the first amplifier comprises a power amplifier, the second path comprises a receive path, and the second amplifier comprises a low noise amplifier.

Example 14 includes amplifier circuitry comprising: a first amplifier; a second amplifier; a substrate; a first transformer operably coupled to an output of the first amplifier; and a second transformer operably coupled to an output of the second amplifier, wherein the first transformer includes a first conductive trace on the substrate and laterally extending around a first opening on the substrate, the second transformer includes a second conductive trace on the substrate, the second conductive trace includes a crossover that overlaps the first opening, and the second conductive trace laterally extends around second and third openings that overlap the first opening and that are smaller than the first opening.

Example 15 includes the amplifier circuitry of example 14, wherein the first conductive trace has a magnetic coupling coefficient with the second conductive trace that is less than or equal to 0.1 across a frequency range of the amplifier circuitry.

Example 16 includes the amplifier circuitry of example 14, wherein the first transformer includes a third conductive trace on the substrate, overlapping the first conductive trace, and laterally extending around the first opening.

Example 17 includes the amplifier circuitry of example 16, wherein the second transformer includes a fourth conductive trace on the substrate, overlapping the second conductive trace, and laterally extending around the second and third openings, the fourth conductive trace having an additional crossover that overlaps the crossover of the second conductive trace.

Example 18 includes the amplifier circuitry of example 17, wherein the first conductive trace laterally surrounds the second conductive trace on a first layer of the substrate and wherein the third conductive trace laterally surrounds the fourth conductive trace on a second layer of the substrate.

Example 19 includes the amplifier circuitry of example 14, wherein: the first conductive trace extends from a first terminal to a second terminal, the second conductive trace extends from a third terminal to a fourth terminal, the first terminal is coupled to a reference potential, the third terminal is coupled to the reference potential, the second terminal is coupled to the fourth terminal by a capacitor, and the second terminal is coupled to an output load of the amplifier circuitry.

Example 20 includes wireless circuitry comprising: an antenna; and power amplifier circuitry communicatively coupled to the antenna and configured to transmit a radio-frequency signal using the antenna, wherein the power amplifier circuitry includes a signal splitter, a signal combiner, a first path coupled between the signal splitter and the signal combiner and having a first amplifier, and a second path coupled between the signal splitter and the signal combiner in parallel with the first path and having a second amplifier, wherein the signal splitter includes a first transformer communicatively coupled to an input of the first amplifier, the signal splitter includes a second transformer communicatively coupled to an input of the second amplifier, the first transformer laterally surrounds the second transformer, and the first transformer is orthogonal to the second transformer.

Example 21 includes circuitry. The circuitry can include a substrate. The circuitry can include a first transformer that includes a first primary winding formed from a first conductive trace on the substrate and that includes a first secondary winding formed from a second conductive trace on the substrate. The circuitry can include a second transformer that includes a second primary winding formed from a third conductive trace on the substrate and that includes a second secondary winding formed from a fourth conductive trace on the substrate, wherein the second conductive trace overlaps the first conductive trace, the fourth conductive trace overlaps the third conductive trace, the first and second conductive traces laterally surround an opening on the substrate, the third and fourth conductive traces overlap the opening, and the third conductive trace includes a crossover.

Example 22 includes the circuitry of example 21, wherein the fourth conductive trace includes an additional crossover that overlaps the crossover.

Example 23 includes the circuitry of example 21, wherein the second conductive trace has a first non-zero magnetic coupling coefficient with the first conductive trace and the fourth conductive trace has a second non-zero magnetic coupling coefficient with the third conductive trace.

Example 24 includes the circuitry of example 23, wherein a first magnetic coupling coefficient between the first conductive trace and the third conductive trace is equal to zero and a second magnetic coupling coefficient between the first conductive trace and the fourth conductive trace is equal to zero.

Example 25 includes the circuitry of example 24, wherein a third magnetic coupling coefficient between the second conductive trace and the third conductive trace is equal to zero and a fourth magnetic coupling coefficient between the second conductive trace and the fourth conductive trace is equal to zero.

Example 26 includes the circuitry of example 21, wherein the third conductive trace and the fourth conductive trace laterally surround a first portion of the opening and a second portion of the opening.

Example 27 includes the circuitry of example 26, wherein current flowing through the third and fourth conductive traces produces a first magnetic field passing through the first portion of the opening and produces a second magnetic field opposite the first magnetic field and passing through the second portion of the opening.

Example 28 includes the circuitry of example 27, wherein additional current flowing through the first and second conductive traces produces a third magnetic field parallel to the first magnetic field and passing through the first and second portions of the opening.

Example 29 includes the circuitry of example 28, wherein the first conductive trace extends between first input terminals of the first transformer, the third conductive trace extends between second input terminals of the second transformer, and the circuitry further comprises: a first amplifier having a first output coupled to the first input terminals; and a second amplifier having a second output coupled to the second input terminals.

Example 30 includes the circuitry of example 29, wherein the first and second transformers are configured to form a signal combiner for the first and second amplifiers.

Example 31 includes the circuitry of example 28, wherein the second conductive trace extends between first output terminals of the first transformer, the fourth conductive trace extends between second output terminals of the second transformer, and the circuitry further comprises: a first amplifier having a first input coupled to the first output terminals; and a second amplifier having a second input coupled to the second output terminals.

Example 32 includes the circuitry of example 31, wherein the first and second transformers are configured to form a signal splitter for the first and second amplifiers.

Example 33 includes wireless circuitry comprising: a first antenna; a second antenna; a first transmit path communicatively coupled to the first antenna; second transmit path communicatively coupled to the second antenna; a first transformer on the first transmit path; and a second transformer on the second transmit path, wherein the first transformer laterally surrounds an opening, the second transformer overlaps the opening, the first transformer is configured to produce a first magnetic field that passes through the opening, and the second transformer is configured to produce a second magnetic field that passes through a first portion of the opening and is configured to produce a third magnetic field that passes through a second portion of the opening, the third magnetic field being opposite the second magnetic field.

Example 34 includes the wireless circuitry of example 33, wherein the third magnetic field and the second magnetic field have an equal magnitude, the first transformer comprises first and second overlapping conductive traces arranged in a loop pattern around the opening, and the second transformer comprises third and fourth overlapping conductive traces in a figure eight pattern within the opening.

Example 35 includes the wireless circuitry of example 33, further comprising: a first power amplifier having a first input communicatively coupled to output terminals of the first transformer; and a second power amplifier having a second input communicatively coupled to output terminals of the second transformer.

Example 36 includes the wireless circuitry of example 36, further comprising: a first power amplifier having a first output communicatively coupled to input terminals of the first transformer; and a second power amplifier having a second output communicatively coupled to input terminals of the second transformer.

Example 37 includes wireless circuitry comprising: a first antenna; a second antenna; a transmit path communicatively coupled to the first antenna; a receive path communicatively coupled to the second antenna; a first transformer on the transmit path; and a second transformer on the receive path, wherein the first transformer laterally surrounds the second transformer, the first transformer is configured to produce a first magnetic field that passes through the second transformer, and the second transformer is configured to produce a second magnetic field that passes through a first portion of the first transformer and is configured to produce a third magnetic field that passes through a second portion of the first transformer, the third magnetic field being opposite the second magnetic field.

Example 38 includes the wireless circuitry of example 37, wherein the third magnetic field and the second magnetic field have an equal magnitude, the first transformer comprises first and second overlapping conductive traces arranged in a loop pattern around an opening, and the second transformer comprises third and fourth overlapping conductive traces in a figure eight pattern within the opening.

Example 39 includes the wireless circuitry of example 37, further comprising: a power amplifier having an input communicatively coupled to output terminals of the first transformer; and a low noise amplifier having an output communicatively coupled to input terminals of the second transformer.

Example 40 includes the wireless circuitry of example 37, further comprising: a power amplifier having an output communicatively coupled to input terminals of the first transformer; and a low noise amplifier having an input communicatively coupled to output terminals of the second transformer.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is illustrative and various modifications can be made to the described embodiments. The foregoing embodiments may be implemented individually or in any combination.

What is claimed is:

1. Circuitry comprising:
a substrate;
a first transformer that includes a first primary winding formed from a first conductive trace on the substrate and that includes a first secondary winding formed from a second conductive trace on the substrate; and
a second transformer that includes a second primary winding formed from a third conductive trace on the substrate and that includes a second secondary winding formed from a fourth conductive trace on the substrate, wherein
the second conductive trace overlaps the first conductive trace,
the fourth conductive trace overlaps the third conductive trace,
the first and second conductive traces laterally surround an opening on the substrate,
the third and fourth conductive traces overlap the opening, and
the third conductive trace includes a crossover.

2. The circuitry of claim 1, wherein the fourth conductive trace includes an additional crossover that overlaps the crossover.

3. The circuitry of claim 1, wherein the second conductive trace has a first non-zero magnetic coupling coefficient with the first conductive trace and the fourth conductive trace has a second non-zero magnetic coupling coefficient with the third conductive trace.

4. The circuitry of claim 3, wherein a first magnetic coupling coefficient between the first conductive trace and the third conductive trace is equal to zero and a second magnetic coupling coefficient between the first conductive trace and the fourth conductive trace is equal to zero.

5. The circuitry of claim 4, wherein a third magnetic coupling coefficient between the second conductive trace and the third conductive trace is equal to zero and a fourth magnetic coupling coefficient between the second conductive trace and the fourth conductive trace is equal to zero.

6. The circuitry of claim 1, wherein the third conductive trace and the fourth conductive trace laterally surround a first portion of the opening and a second portion of the opening.

7. The circuitry of claim 6, wherein current flowing through the third and fourth conductive traces produces a first magnetic field passing through the first portion of the opening and produces a second magnetic field opposite the first magnetic field and passing through the second portion of the opening.

8. The circuitry of claim 7, wherein additional current flowing through the first and second conductive traces produces a third magnetic field parallel to the first magnetic field and passing through the first and second portions of the opening.

9. The circuitry of claim 8, wherein the first conductive trace extends between first input terminals of the first transformer, the third conductive trace extends between second input terminals of the second transformer, and the circuitry further comprises:
a first amplifier having a first output coupled to the first input terminals; and
a second amplifier having a second output coupled to the second input terminals.

10. The circuitry of claim 9, wherein the first and second transformers are configured to form a signal combiner for the first and second amplifiers.

11. The circuitry of claim 8, wherein the second conductive trace extends between first output terminals of the first transformer, the fourth conductive trace extends between second output terminals of the second transformer, and the circuitry further comprises:
a first amplifier having a first input coupled to the first output terminals; and
a second amplifier having a second input coupled to the second output terminals.

12. The circuitry of claim 11, wherein the first and second transformers are configured to form a signal splitter for the first and second amplifiers.

13. Wireless circuitry comprising:
a first antenna;
a second antenna;
a first transmit path communicatively coupled to the first antenna;
a second transmit path communicatively coupled to the second antenna;
a first transformer on the first transmit path; and
a second transformer on the second transmit path, wherein
the first transformer laterally surrounds an opening,
the second transformer overlaps the opening,
the first transformer is configured to produce a first magnetic field that passes through the opening, and
the second transformer is configured to produce a second magnetic field that passes through a first portion of the opening and is configured to produce a third magnetic field that passes through a second portion of the opening, the third magnetic field being opposite the second magnetic field.

14. The wireless circuitry of claim 13, wherein the third magnetic field and the second magnetic field have an equal magnitude, the first transformer comprises first and second overlapping conductive traces arranged in a loop pattern around the opening, and the second transformer comprises third and fourth overlapping conductive traces in a figure eight pattern within the opening.

15. The wireless circuitry of claim 13, further comprising:
a first power amplifier having a first input communicatively coupled to output terminals of the first transformer; and
a second power amplifier having a second input communicatively coupled to output terminals of the second transformer.

16. The wireless circuitry of claim 13, further comprising:
a first power amplifier having a first output communicatively coupled to input terminals of the first transformer; and
a second power amplifier having a second output communicatively coupled to input terminals of the second transformer.

17. Wireless circuitry comprising:
a first antenna;
a second antenna;
a transmit path communicatively coupled to the first antenna;
a receive path communicatively coupled to the second antenna;
a first transformer on the transmit path; and
a second transformer on the receive path, wherein
the first transformer laterally surrounds the second transformer,
the first transformer is configured to produce a first magnetic field that passes through the second transformer, and
the second transformer is configured to produce a second magnetic field that passes through a first portion of the first transformer and is configured to produce a third magnetic field that passes through a second portion of the first transformer, the third magnetic field being opposite the second magnetic field.

18. The wireless circuitry of claim 17, wherein the third magnetic field and the second magnetic field have an equal magnitude, the first transformer comprises first and second overlapping conductive traces arranged in a loop pattern around an opening, and the second transformer comprises third and fourth overlapping conductive traces in a figure eight pattern within the opening.

19. The wireless circuitry of claim 17, further comprising:
a power amplifier having an input communicatively coupled to output terminals of the first transformer; and
a low noise amplifier having an output communicatively coupled to input terminals of the second transformer.

20. The wireless circuitry of claim 17, further comprising:
a power amplifier having an output communicatively coupled to input terminals of the first transformer; and
a low noise amplifier having an input communicatively coupled to output terminals of the second transformer.
